(19) United States
(12) Patent Application Publication
(10) Pub. No.: US 2024/0228876 A1
(43) Pub. Date: Jul. 11, 2024

(54) TREATMENT LIQUID FOR MANUFACTURING SEMICONDUCTOR AND METHOD OF TREATING OBJECT TO BE TREATED

(71) Applicant: FUJIFILM Corporation, Tokyo (JP)

(72) Inventors: Yuta SHIGENOI, Haibara-gun (JP); Atsushi Mizutani, Haibara-gun (JP); Tomonori Takahashi, Haibara-gun (JP)

(73) Assignee: FUJIFILM Corporation, Tokyo (JP)

(21) Appl. No.: 18/603,578

(22) Filed: Mar. 13, 2024

Related U.S. Application Data
(63) Continuation of application No. PCT/JP22/33582, filed on Sep. 7, 2022.

(30) Foreign Application Priority Data
Sep. 21, 2021 (JP) 2021-153510

(51) Int. Cl. C09K 13/00; H01L 21/306

(52) U.S. Cl. CPC C09K 13/00; H01L 21/30604

(57) ABSTRACT

An object of the present invention is to provide a treatment liquid for producing a semiconductor, which is capable of selectively removing Si in a case of being applied to an object to be treated containing SiGe and Si. The treatment liquid for manufacturing a semiconductor according to the present invention includes: a nitrogen-containing polymer; a quaternary ammonium hydroxide; an organic solvent having an SP value of 25 MPa^{1/2} or more; and water. Polyalkyleneimine is excluded from the nitrogen-containing polymer.

### CROSS-REFERENCE TO RELATED APPLICATIONS

This application is a Continuation of PCT International Application No. PCT/JP2022/033582 filed on Sep. 7, 2022, which claims priority under 35 U.S.C. § 119(a) to Japanese Patent Application No. 2021-153510 filed on Sep. 21, 2021. The above applications are hereby expressly incorporated by reference, in their entirety, into the present application.

### BACKGROUND OF THE INVENTION

### 1. Field of the Invention

The present invention relates to a treatment liquid for manufacturing a semiconductor and a method of treating an object to be treated.

### 2. Description of the Related Art

In a case of forming a circuit and an element, it is general to perform an etching process using a chemical liquid. In this case, since a plurality of materials may be present on the substrate, it is desirable that the chemical liquid used for etching is a chemical liquid capable of selectively removing only a specific material.

For example, JP2019-050364A discloses an etchant suitable for selectively removing silicon (hereinafter, also simply referred to as “Si”) with respect to silicon germanium (hereinafter, also simply referred to as “SiGe”) from a microelectronic device. More specifically, JP2019-050364A discloses that an etchant contains water, at least one of a quaternary ammonium compound or an amine compound, a water-miscible solvent, and may contain at least one of a surfactant or a corrosion inhibitor.

### SUMMARY OF THE INVENTION

The present inventors have studied the etchant (treatment liquid for producing a semiconductor) described in JP2019-050364A, and have found that the etchant does not have sufficient ability to selectively remove Si with respect to SiGe and needs to be further improved.

JP2019-050364A discloses that the etchant may contain polyethyleneimine as a surfactant. The present inventors have also studied a treatment liquid for manufacturing a semiconductor which contains polyethyleneimine, and have found that the above-described ability is not sufficient.

Therefore, an object of the present invention is to provide a treatment liquid for producing a semiconductor, which is capable of selectively removing Si in a case of being applied to an object to be treated containing SiGe and Si.

Another object of the present invention is to provide a method of treating an object to be treated using the treatment liquid for producing a semiconductor.

As a result of intensive studies to solve the above-described problems, the present inventors have completed the present invention. That is, the present inventors have found that the above-described problems can be solved by the following configuration.
[1] A treatment liquid for producing a semiconductor, the treatment liquid comprising:
   a nitrogen-containing polymer;
   a quaternary ammonium hydroxide;
   an organic solvent having an SP value of 25 MPa1 2 or more; and
   water,
   provided that polyalkyleneimine is excluded from the nitrogen-containing polymer.
[2] The treatment liquid for manufacturing a semiconductor according to [1], in which the treatment liquid is used for an object to be treated containing silicon germanium and silicon.
[3] The treatment liquid for manufacturing a semico according to [1] or [2], in which a content of the organic solvent is 40 mass % or more with respect to a total mass of the treatment liquid for producing a semiconductor.
[4] The treatment liquid for manufacturing a semiconductor according to any one of [1] to [3], in which the organic solvent does not include a compound having an amide structure.
[5] The treatment liquid for manufacturing a semiconductor according to any one of [1] to [4], in which the organic solvent is a compound having at least one of a hydroxy group or an amino group.
[6] The treatment liquid for manufacturing a semiconductor according to any one of [1] to [5], in which pH is more than 7.0.
[7] The treatment liquid for manufacturing a semiconductor according to any one of [1] to [6], in which pH is 11.0 or more.
[8] The treatment liquid for manufacturing a semiconductor according to any one of [1] to [7], in which a weight average molecular weight of the nitrogen-containing polymer is 1,000 or more.
[9] The treatment liquid for manufacturing a semiconductor according to any one of [1] to [8], in which the nitrogen-containing polymer contains a repeating unit having a structure selected from the group consisting of a primary amine structure, a secondary amine structure, a tertiary amine structure, and a quaternary ammonium salt structure.
[10] The treatment liquid for manufacturing a semiconductor according to [9], in which the nitrogen-containing polymer contains a repeating unit having the quaternary ammonium salt structure.
[11] The treatment liquid for manufacturing a semiconductor according to any one of [1] to [9], in which the nitrogen-containing polymer contains a repeating unit selected from the group consisting of a repeating unit represented by Formula (1) described later, a repeating unit represented by Formula (2) described later, and a repeating unit represented by Formula (3) described later.
[12] The treatment liquid for manufacturing a semiconductor according to [11], in which the nitrogen-containing polymer contains the repeating unit represented by Formula (1).
[13] The treatment liquid for manufacturing a semiconductor according to any one of [1] to [12], in which the content of the nitrogen-containing polymer is 0.1 to 2.0 mass % with respect to the total mass of the treatment liquid for producing a semiconductor.
[14] A method of treating an object to be treated, the method comprising:
bringing an object to be treated containing silicon germanium and silicon into contact with the treatment liquid according to any one of [1] to [13] remove the silicon.

According to the present invention, it is possible to provide a treatment liquid for producing a semiconductor, which is capable of selectively removing Si in a case of being applied to an object to be treated containing SiGe and Si.

In addition, according to the present invention, it is also possible to provide a method of treating an object to be treated.

### DESCRIPTION OF THE PREFERRED EMBODIMENTS

Hereinafter, the present invention will be described in detail.

The constituent features described below may be described based on representative embodiments of the present invention, but the present invention is not limited to such embodiments.

Hereinafter, the meaning of each description in the present specification is shown.

In the present specification, a numerical range represented by using “to” means a range including numerical values described before and after “to” as a lower limit and an upper limit.

In the present specification, “ppm” is an abbreviation for “parts per million” and means 10⁻⁶. In addition, “ppb” is an abbreviation for “parts per billion”, and means 10⁻⁹. “ppt” is an abbreviation for “parts per trillion” and means 10⁻¹².

In the present specification, in a case where two or more kinds of certain components are present, the “content” of the components means the total content of the two or more kinds of components.

In the present specification, “silicon” and “Si” refer to a material substantially composed of only a Si element. The term “substantially” means that the content of the Si element is 90 mass % or more with respect to the total mass of the material. Therefore, as long as the content of the Si element is within the above range, other elements (excluding the Ge element) may be contained.

In addition, in the present specification, “silicon germanium” and “SiGe” refer to a material substantially composed of only a Si element and a Ge element. The term “substantially” means that the total content of the Si element and the Ge element is 90 mass % or more with respect to the total mass of the material. Therefore, as long as the total content of the Si element and the Ge element is within the above range, other elements may be contained. In addition, in the silicon germanium, the content ratio between the Si element and the Ge element is not particularly limited, and the mass ratio of the content of the Ge element to the total amount of the Si element and the Ge element is preferably 5 to 50 mass %.

Unless otherwise specified, the term “exposure” includes exposure with far ultraviolet rays typified by those emitted from a mercury lamp and an excimer laser, X-rays, or EUV light, and drawing with particle beams such as electron beams or ion beams.

The term “preparation” includes procurement of a predetermined material by purchases or the like, in addition the preparation by synthesizing or compounding a specific material.

Unless otherwise specified, the bonding direction of a divalent group (for example, —COO—) may be any. In a case where Y in a compound represented by “X-Y-Z” is —COO—, the compound may be any of “X—O—CO—Z” or “X—CO—O—Z”.

In the present specification, “SP value” means “value of the solubility parameter”, and “solubility parameter” means Hansen solubility parameter according to the formula described in Hansen solubility parameter: A User's Handbook, Second Edition, C. M. Hansen (2007), Taylor and Francis Group, LLC (HSPiP Manual).

The “SP value” in the present specification refers to a value obtained by calculating using “Hansen Solubility Parameters in Practice HSPiP Fifth Edition” (software version: 5.1.03) according to Formula (S).

$${( SP value )}^{2} = {δ}_{d}^{2} + {δ}_{p}^{2} + {δ}_{h}^{2} \qquad Formula ( S )$$

In Formula (S), δ_{d} represents energy due to a dispersion force, δₚ represents energy due to a dipole-dipole interaction, and δₕ represents energy due to a hydrogen bond. The unit of the SP value is MPa^{1/2}(MPa^{0.5}).

In the present specification, unless otherwise specified, the weight average molecular weight (Mw) and the number average molecular weight (Mn) are values converted using polystyrene as a standard substance. The weight average molecular weight (Mw) and the number average molecular weight (Mn) are measured by a gel permeation chromatography (GPC) analyzer using TSKgel GMHxL, TSKgel G4000HxL, or TSKgel G2000HxL (all trade names manufactured by Tosoh Corporation) as a column, tetrahydrofuran (THF) as an eluent, a differential refractometer as a detector, and polystyrene as a standard substance.

In the present specification, unless otherwise specified, the molecular weight of a compound having a molecular weight distribution is the weight average molecular weight (Mw).

### <Treatment Liquid for Manufacturing Semiconductor>

A treatment liquid for manufacturing a semiconductor according to an embodiment of the present invention (hereinafter, also simply referred to as a “treatment liquid”) contains a nitrogen-containing polymer, a quaternary ammonium hydroxide, an organic solvent having an SP value of 25 MPa^{1/2} or more, and water. Provided that polyalkyleneimine is excluded from the nitrogen-containing polymer.

In a case where the treatment liquid according to an embodiment of the present invention has the above-described configuration, the mechanism by which Si can be selectively removed (etched) in a case where having is applied to an object to be treated containing SiGe and Si is not necessarily clear, but the present inventors presume as follows.

The treatment liquid contains a quaternary ammonium hydroxide and water to exhibit an etching ability for both Si and SiGe. However, it is considered that in a case where the treatment liquid further contains a nitrogen-containing polymer, so that only etching of SiGe is suppressed and Si can be selectively etched. Further, it is considered that in a case where the treatment liquid contains an organic solvent having an SP value of 25 MPa^{1/2} or more, so that the etching of SiGe can be further suppressed and Si can be selectively etched.

Hereinafter, components which may be contained in the treatment liquid will be described in detail.

Hereinafter, in a case where the treatment liquid is applied to an object to be treated containing SiGe and Si, the fact that Si can be selectively removed (etched) is also referred to as “excellent in Si selective removability”.

### [Nitrogen-Containing Polymer]

The treatment liquid according to an embodiment of the present invention contains a nitrogen-containing polymer.

The nitrogen-containing polymer refers to a polymer containing a nitrogen atom in a part of the polymer. The polymer refers to a compound obtained by polymerizing a monomer, and refers to a compound having a weight average molecular weight of 500 or more.

The nitrogen-containing polymer may contain a nitrogen atom in a part of the polymer, but preferably contains a repeating unit having a nitrogen atom (hereinafter, also referred to as a “nitrogen-containing unit”). In addition, the nitrogen-containing polymer may also contain a repeating unit other than the nitrogen-containing unit (hereinafter, also referred to as “other units”).

### (Nitrogen-Containing Unit)

The form of the nitrogen atom contained in the nitrogen-containing unit is not particularly limited, and the nitrogen atom may be cationized. In addition, in the nitrogen atom contained in the nitrogen-containing unit, all the bonds between the nitrogen atom and the surrounding atoms may be a single bond or may include a double bond or a triple bond.

Examples of the form of the nitrogen atom in the nitrogen-containing unit include structures represented by Formulae (A) to (D).

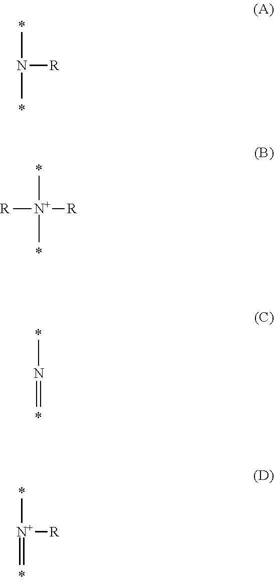

In Formulae (A) to (D), * represents a bonding position.

In Formulae (A), (B), and (D), R each independently represents a hydrogen atom or a monovalent substituent.

Examples of the structure having a structure represented by Formula (A) include a primary amine structure, a secondary amine structure, and a tertiary amine structure. The primary amine structure refers to a structure in which, among three atoms bonded to a nitrogen atom, two atoms are hydrogen atoms and one atom is an atom other than a hydrogen atom (for example, a carbon atom). The secondary amine structure refers to a structure in which, among three atoms bonded to a nitrogen atom, one atom is a hydrogen atom and two atoms are atoms other than a hydrogen atom (for example, carbon atoms). The tertiary amine structure refers to a structure in which three atoms bonded to a nitrogen atom are atoms other than hydrogen atoms (for example, carbon atoms).

Examples of the structure having a structure represented by Formula (B) include a quaternary ammonium salt structure. The quaternary ammonium salt structure refers to a salt in which a nitrogen atom is cationized, and four atoms bonded to the nitrogen atom are atoms other than hydrogen atoms (for example, carbon atoms), and are electrostatically bonded to an anion.

Examples of the structure having a structure represented by Formula (C) include an imine structure and an aromatic imine structure (a nitrogen atom in a pyridine ring, an azole ring, and the like). The imine structure refers to a structure in which a nitrogen atom is bonded to two atoms, the bond to one atom is a single bond, and the bond to the other atom is a double bond.

Examples of the structure having a structure represented by Formula (D) include an iminium salt structure (a salt structure in which a nitrogen atom in an imine structure is cationized and electrostatically bonded to an anion), and an aromatic iminium salt structure (a salt structure in which a nitrogen atom in a pyridine ring, an azole ring or the like is cationized and electrostatically bonded to an anion).

Examples of the structure in which the bond between a nitrogen atom and a surrounding atom includes a triple bond include a nitrile structure. The nitrile structure refers to a structure in which a nitrogen atom forms a triple bond with one atom, and is included in, for example, a nitrile group.

From the viewpoint that the Si selective removal properties are more excellent, the form of the nitrogen atom contained in the nitrogen-containing unit is preferably a structure represented by Formula (A) or (B). Therefore, as the form of the nitrogen atom contained in the nitrogen-containing unit, a primary amine structure, a secondary amine structure, a tertiary amine structure, or a quaternary ammonium salt structure is preferable. From the viewpoint that the Si selective removability is more excellent, the form of the nitrogen atom contained in the nitrogen-containing unit is more preferably a secondary amine structure, a tertiary amine structure, or a quaternary ammonium salt structure, still more preferably a tertiary amine structure or a quaternary ammonium salt structure, and particularly preferably a quaternary ammonium salt structure.

In addition, the nitrogen atom contained in the nitrogen-containing unit may be contained in either or both of the main chain and the side chain. In the present specification, the “main chain” represents a relatively longest bonded chain in the molecule of a polymer compound constituting a resin, and the “side chain” represents an atomic group branched from the main chain.

From the viewpoint that the Si selective removability is more excellent, it is preferable that the nitrogen atom contained in the nitrogen-containing unit is contained at least in the side chain.

Examples of a more specific structure of the nitrogen-containing unit include repeating units represented by Formulae (1) to (3).

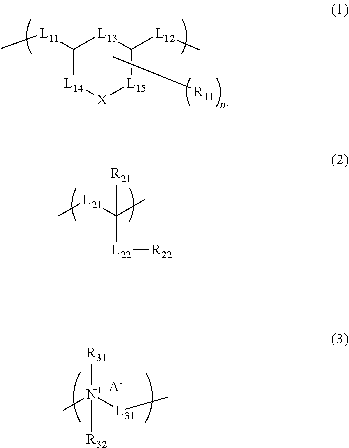

In Formula (1), L₁₁ to L₁₅ each independently represent a single bond or a divalent linking group.

Examples of the divalent linking group represented by L₁₁ and L₁₂ include an alkylene group, a cycloalkylene group, an arylene group, —O—, —S—, —CO—, —COO—, —CONH—, —SO₂—, and a group formed by combining one or more divalent linking groups selected from the group consisting of —O—, —S—, —CO—, —COO—, —CONH—, and —SO₂— with an alkylene group, a cycloalkylene group, and an arylene group.

The alkylene group may be either linear or branched, and is preferably linear. The number of carbon atoms of the alkylene group is not particularly limited, but is preferably 1 to 10, more preferably 1 to 5, and still more preferably 1 to 3.

The cycloalkylene group may be either monocyclic or polycyclic, and is preferably monocyclic. The number of carbon atoms of the cycloalkylene group is not particularly limited, but is preferably 5 to 12 and more preferably 5 to 8.

The arylene group may be either monocyclic or polycyclic, and is preferably monocyclic. In addition, the arylene group may be a heteroarylene group containing an atom other than a carbon atom as a ring member atom. The number of ring member atoms in the arylene group is not particularly limited, but is preferably 5 to 15 and more preferably 5 to 10.

Among the above, L₁₁ and L₁₂ are preferably a single bond, an alkylene group, or a group formed by combining an alkylene group and —SO₂—, and more preferably an alkylene group. More specifically, as the alkylene group represented by L₁₁ and L₁₂, a methylene group, an ethylene group, or a propylene group is preferable.

In Formula (1), L₁₃ to L₁₅ each independently represent a single bond or a divalent linking group.

Examples of the divalent linking group represented by L₁₃ to L₁₅ include an alkylene group, —O—, —S—, —CO—, —COO—, —CONH—, —SO₂—, and a group formed by combining one or more divalent linking groups selected from the group consisting of —O—, —S—, —CO—, —COO—, —CONH—, and —SO₂— with an alkylene group. A preferred form of the alkylene group is as described above.

Among the above, L₁₃ is preferably a single bond or an alkylene group, and more preferably a single bond. L₁₄ and L₁₅ are preferably a single bond or an alkylene group, and more preferably an alkylene group. More specifically, as the alkylene group represented by L₁₄ and L₁₅, a methylene group or an ethylene group is preferable.

In Formula (1), X represents a divalent linking group containing a nitrogen atom.

As the divalent linking group containing a nitrogen atom, a divalent linking group having a secondary amine structure, a tertiary amine structure, or a quaternary ammonium salt structure is preferable. More specifically, a divalent linking group represented by Formula (X1) or a divalent linking group represented by Formula (X2) is preferable.

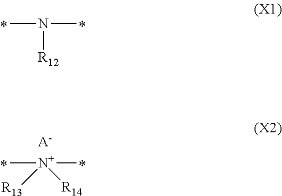

In Formulae (X1) and (X2), * represents a bonding position.

In Formula (X1), R₁₂ represents a hydrogen atom or a monovalent substituent.

Examples of the monovalent substituent represented by R₁₂ include an alkyl group having 1 to 6 carbon atoms, which may have a substituent. The alkyl group may be linear or branched, and is preferably linear. The number of carbon atoms of the alkyl group is preferably 1 to 4 and more preferably 1 to 3. Examples of the substituent of the alkyl group which may have a substituent include a halogen atom and a hydroxy group.

Among the above, R₁₂ is preferably a hydrogen atom or an unsubstituted alkyl group, and more preferably an unsubstituted alkyl group. More specifically, the unsubstituted alkyl group is preferably a methyl group, an ethyl group, or a propyl group.

The divalent linking group represented by Formula (X1) may form a salt with an acid. Examples of the acid that forms a salt with the divalent linking group represented by Formula (X1) include hydrogen chloride, hydrogen bromide, nitric acid, amidosulfuric acid, acetic acid, ethylsulfuric acid, and methanesulfonic acid.

In Formula (X2), R₁₃ and R₁₄ each independently represent a monovalent substituent. Examples of the monovalent substituent represented by R₁₃ and R₁₄ include the monovalent substituent represented by R₁₂, and a preferred form thereof is also the same.

In Formula (X2), A⁻ represents a monovalent anion.

The monovalent anion represented by A⁻ may be an inorganic anion or an organic anion. Examples of the inorganic anion include a halogen ion and a nitrate ion. Examples of the organic anion include an acetate ion, an ethyl sulfate ion, and a methanesulfonate ion. Among these, a halogen ion or an ethyl sulfate ion is preferable. Examples of the halogen ion include a fluoride ion, a chloride ion, a bromide ion, and an iodide ion, and a chloride ion is preferable.

In Formula (1), R₁₁ represents a monovalent substituent. In a case where a plurality of R₁₁'s are present, the plurality of R₁₁'s each independently represent a monovalent substituent.

Examples of the monovalent substituent represented by R₁₁ include an alkyl group which may have a substituent, a halogen atom, and a hydroxy group. The alkyl group which may have a substituent is the same as the alkyl group which may have a substituent, described as the monovalent substituent represented by R₁₂.

In Formula (1), n₁ represents an integer of 0 to 5.

n₁ is preferably 0 to 3, more preferably 0 to 2, still more preferably 0 or 1, and particularly preferably 0.

In Formula (2), L₂₁ represents a divalent linking group.

Examples of the divalent linking group represented by L₂₁ include the divalent linking groups represented by L₁₁ and L₁₂, and a preferred form thereof is also the same. That is, as the divalent linking group represented by L₂₁, an alkylene group is preferable, and a methylene group, an ethylene group, or a propylene group more preferable. One or more hydrogen atoms of the alkylene group may be substituted with a monovalent substituent, and examples of the monovalent substituent include a halogen atom and a hydroxy group.

In Formula (2), L₂₂ represents a single bond or a divalent linking group.

Examples of the divalent linking group represented by L₂₂ include the divalent linking groups represented by L₁₁ and L₁₂. As the divalent linking group represented by L₂₂, —COO—, —CONH—, an alkylene group, or a group formed by combining one or more divalent linking groups selected from the group consisting of —O—, —S—, —CO—, —COO—, —CONH—, and —SO₂— with an alkylene group is preferable.

Among the above, L₂₂ is preferably a single bond, an alkylene group, or a —COO— alkylene group, and more preferably an alkylene group.

In Formula (2), R₂₁ represents a hydrogen atom or a monovalent substituent.

Examples of the monovalent substituent represented by R₂₁ include a halogen atom and an alkyl group having 1 to 3 carbon atoms. Among these, R₂₁ is preferably a hydrogen atom or an alkyl group having 1 to 3 carbon atoms.

In Formula (2), R₂₂ represents a monovalent substituent containing a nitrogen atom. As the monovalent substituent containing a nitrogen atom represented by R₂₂, the monovalent substituent having the structures represented by Formulae (A) to (D) is preferable, and the monovalent substituent represented by Formulae (B1) to (B8) is more preferable.

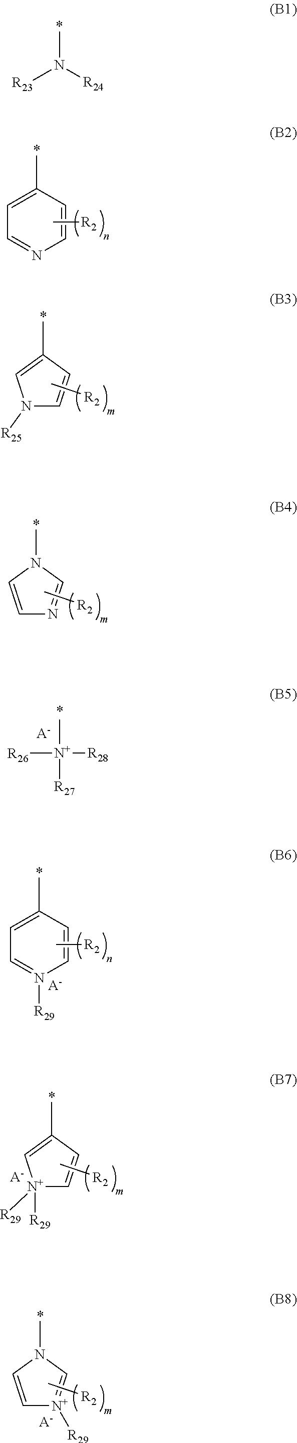

In Formulae (B1) to (B8), * represents a bonding position.

In Formulae (B1) and (B3), R₂₃ to R₂₅ each independently represent a hydrogen atom or a monovalent substituent. Examples of the monovalent substituent represented by R₂₃ to R₂₅ include the monovalent substituent represented by R₁₂. Among these, R₂₃ to R₂₅ are preferably a hydrogen atom or an unsubstituted alkyl group, and more preferably a hydrogen atom.

In Formulae (B5) to (B8), R₂₆ to R₂₉ each independently represent a monovalent substituent. Examples of the monovalent substituent represented by R₂₆ to R₂₉ include the monovalent substituents represented by R₁₂. Among these, in Formulae (B5) to (B8), R₂₆ to R₂₉ are preferably an unsubstituted alkyl group.

In Formulae (B2) to (B4) and (B6) to (B8), R₂ represents a monovalent substituent. In a case where a plurality of R₂'s are present, the plurality of R₂'s each independently represent a monovalent substituent.

Examples of the monovalent substituent represented by R₂ include the same groups as those of the monovalent substituents represented by R₁₁.

In Formulae (B3), (B4), (B7), and (B8), m represents an integer of 0 to 4.

n is preferably 0 to 2, more preferably 0 or 1, and still more preferably 0.

In Formulae (B5) to (B8), A represents a monovalent anion. Examples of A⁻ in Formulae (B5) to (B8) include the same anion as A⁻ in Formula (X2), and a preferred form thereof is also the same.

The monovalent substituent represented by Formulae (B1) to (B4) may form a salt with an acid. Examples of the acid that forms a salt with the monovalent substituent represented by Formulae (B1) to (B4) include an acid that form a salt with the divalent linking group represented by Formula (X1).

Among the above, as the monovalent substituent containing a nitrogen atom represented by R₂₂, the monovalent substituent represented by Formula (B1), the monovalent substituent represented by Formula (B2), or the monovalent substituent represented by Formula (B5) is preferable, and the monovalent substituent represented by Formula (B1) is preferable.

In Formula (3), L₃₁ represents a divalent linking group.

Examples of the divalent linking group represented by L₃₁ include the divalent linking groups represented by L₁₁ and L₁₂, and a preferred form thereof is also the same. That is, as divalent linking group represented by L₂₁, an alkylene group is preferable, and a methylene group, an ethylene group, or a propylene group is more preferable. One or more hydrogen atoms of the alkylene group may be substituted with a monovalent substituent, and examples of the monovalent substituent include a halogen atom and a hydroxy group. Examples of the form in which the hydrogen atom of the alkylene group is substituted with a monovalent substituent include —CH₂—CHOH—CH₂—.

In Formula (3), R₃₁ and R₃₂ each independently represent a monovalent substituent.

Examples of the monovalent substituent represented by R₃₁ and R₃₂ include the monovalent substituents represented by R₁₂, and a preferred form thereof is also the same. That is, as the monovalent substituent represented by R₃₁ and R₃₂, an unsubstituted alkyl group is preferable, and a methyl group, an ethyl group, or a propyl group is more preferable.

In Formula (3), A⁻ represents a monovalent anion.

Examples of A⁻ in Formula (3) include the same anions as A⁻ in Formula (X2), and a preferred form thereof is also the same.

The repeating unit represented by Formulae (1) and (2) is a form having a nitrogen atom in a side chain, and the repeating unit represented by Formula (3) is a form having a nitrogen atom in a main chain.

From the viewpoint that the Si selective removability is more excellent, as the nitrogen-containing unit contained in the nitrogen-containing polymer, among Formulae (1) to (3), a repeating unit represented by Formula (1) or (3) is preferable, and a repeating unit represented by Formula (1) is more preferable.

The nitrogen-containing polymer may contain a nitrogen-containing unit other than the units described above.

The other nitrogen-containing unit is not particularly limited, and may be a known nitrogen-containing unit. The other nitrogen-containing unit may be a repeating unit in which each of the repeating units represented by Formulae (1) to (3) is crosslinked with a crosslinkable group or a crosslinkable molecule. Examples of the crosslinkable group include an epoxy group and an ethylenically unsaturated group. Examples of the crosslinkable molecule include epichlorohydrin and formaldehyde.

Examples of the other nitrogen-containing units include repeating units derived from acrylonitrile.

The nitrogen-containing polymer may contain a plurality of kinds of nitrogen-containing units.

The total content of the nitrogen-containing units is preferably 5 to 100 mass %, more preferably 20 to 100 mass %, and still more preferably 40 to 100 mass % with respect to the total mass of the nitrogen-containing polymer.

The total content of the nitrogen-containing units is preferably 5 to 100 mol %, more preferably 20 to 100 mol %, and still more preferably 40 to 100 mol % with respect to all the repeating units of the nitrogen-containing polymer.

(Other units)

Other units which may be contained in the nitrogen-containing polymer are not particularly limited, and may be known repeating units.

Examples of the other units include repeating units based on a monomer having an ethylenically unsaturated group. Examples of the monomer having an ethylenically unsaturated group include carboxylic acid having an ethylenically unsaturated group.

Examples of the carboxylic acid having an ethylenically unsaturated group include acrylic acid, methacrylic acid, fumaric acid, cinnamic acid, crotonic acid, itaconic acid, 4-vinylbenzoic acid, maleic acid, maleic anhydride, and a salt thereof. In addition, examples of the carboxylic acid having an ethylenically unsaturated group may be a condensation compound or an addition compound of the carboxylic acid with a compound having a hydroxy group, a compound having an amino group, and a compound having a glycidyl group. Examples of the compound include an ester compound of acrylic acid or methacrylic acid with a compound having a hydroxy group, and a half ester compound of maleic acid with a compound having a hydroxy group.

As the other units, repeating units based on acrylic acid, methacrylic acid, or maleic acid are preferable.

The nitrogen-containing polymer may contain a plurality of kinds of the other units.

The content of the other units is preferably 0 to 95 mass %, more preferably 0 to 80 mass %, and still more preferably 0 to 60 mass % with respect to the total mass of the nitrogen-containing polymer.

The content of the nitrogen-containing unit is preferably 0 to 95 mass %, more preferably 0 to 80 mass %, and still more preferably 0 to 60 mass % with respect to all the repeating units of the nitrogen-containing polymer.

Specific examples of the nitrogen-containing polymer include polymers synthesized by using each of an allylamine and a salt thereof, an N-alkylallylamine and a salt thereof, an N,N-dialkylallylamine and a salt thereof, a trialkylallylammonium salt, a diallylamine and a salt thereof, an N-alkyldiallylamine and a salt thereof, and an N,N-dialkylammonium salts as a monomer. Examples of the alkyl group in each of the monomers each independently include a methyl group and an ethyl group. Examples of the compound that forms a salt with amine include hydrogen chloride (hydrochloric acid), amidosulfuric acid, acetic acid, and ethylsulfuric acid. Examples of the counter anion of the ammonium salt include a chloride ion.

The polymer synthesized using diallylamine or the like as a monomer is a polymer containing a repeating unit represented by Formula (1).

Specific examples of the compound name of the polymer include polyallylamine, polyallylamine hydrochloride, polydiallylamine, polydiallylamine hydrochloride, poly(dimethyldiallylammonium chloride), and poly(methylethyldimethylammonium ethyl sulfate).

In addition, a copolymer synthesized from two or more kinds of monomers selected from the above monomers can also be exemplified as the nitrogen-containing polymer. Examples of the copolymer include a copolymer synthesized by using allylamine and diallylamine as monomers, and a copolymer synthesized using an allylamine salt and a diallylamine salt as monomers.

Further, copolymers synthesized using the above monomers and maleic acid as monomers can also be exemplified as the nitrogen-containing polymer. Examples of the copolymer include a copolymer synthesized using diallylamine and maleic acid as monomers.

Specific examples of a nitrogen-containing resin include resins having the skeleton structures represented by Formulae (P-1) to (P-23). In Formulae (P-1) to (P-23), a repeating unit denoted by a reference sign m is defined as a first repeating unit, and a repeating unit denoted by a reference sign n is defined as a second repeating unit.

A plurality of repeating units are described in the skeleton structures represented by Formulae (P-1) to (P-23), and the bonding form of the plurality of repeating units is not particularly limited. For example, a plurality of repeating units may be randomly bonded (so-called random copolymer), may be alternately bonded (so-called alternating copolymer), or may be bonded in a block form (so-called block copolymer).

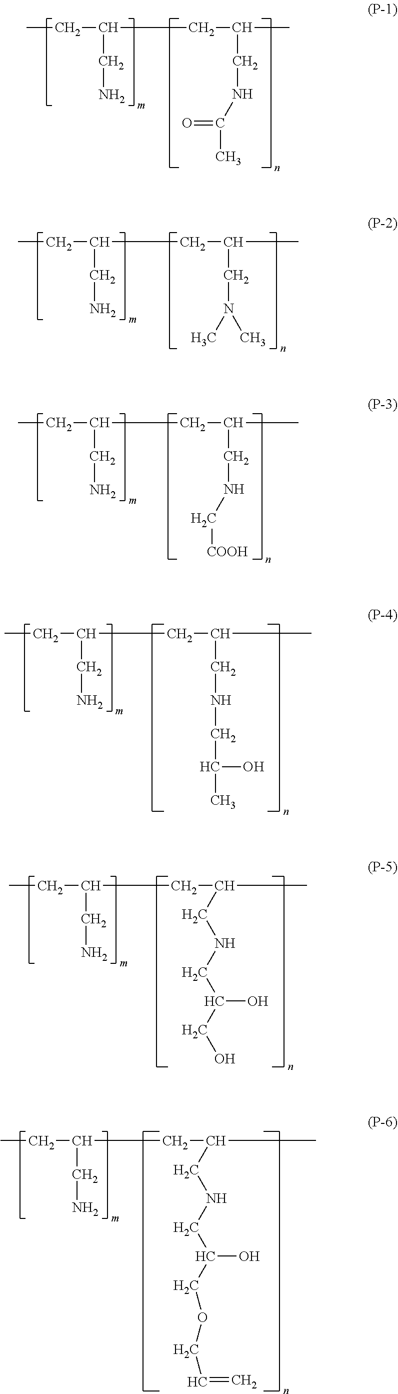

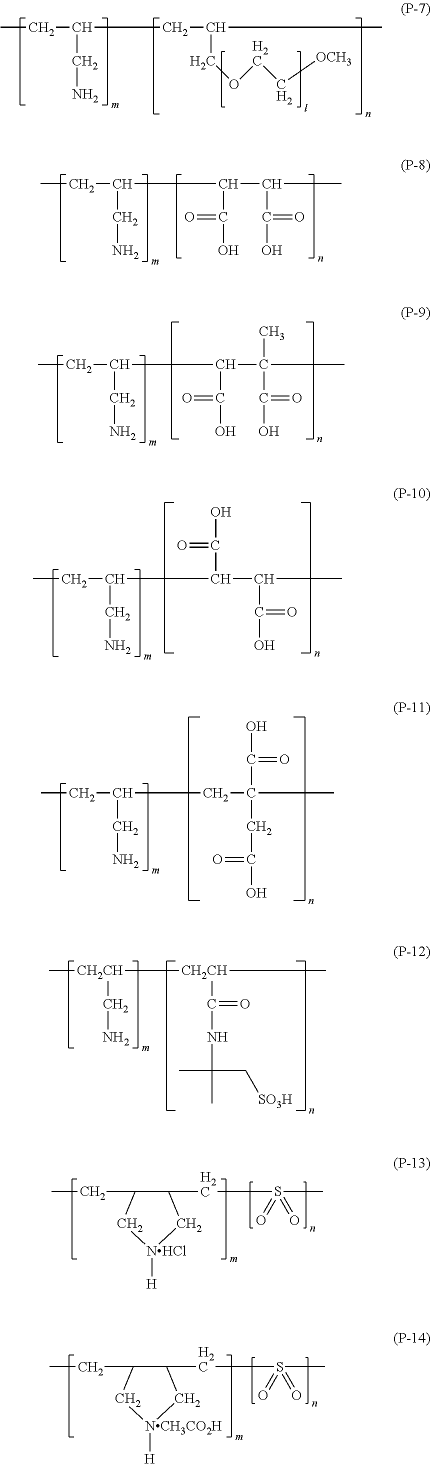

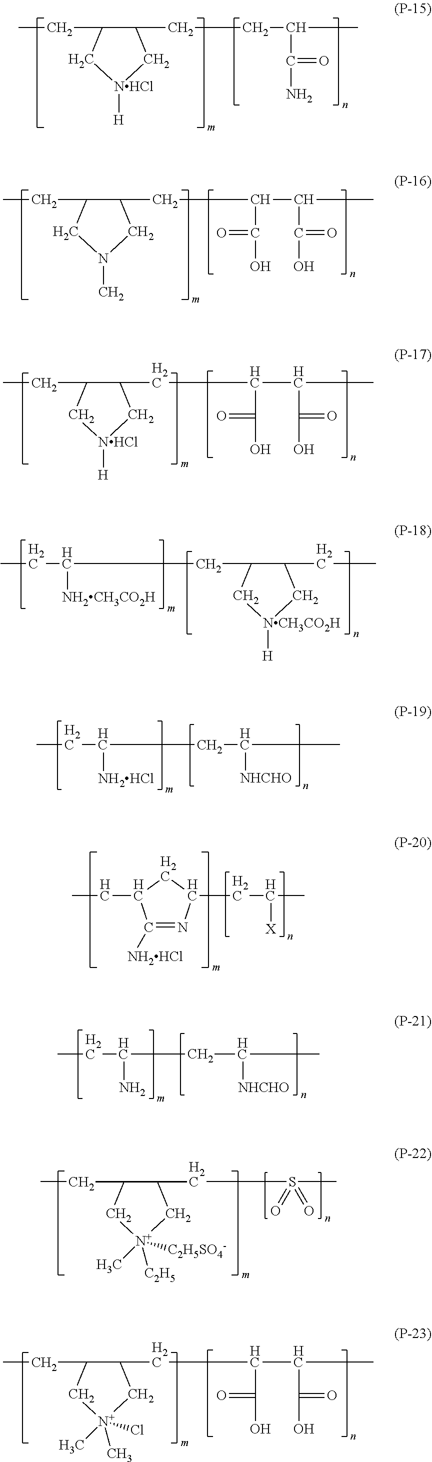

In Formulae (P-1) to (P-23), the ratio (m/n) of the number of moles (m) of the first repeating unit to the number of moles (n) of the second repeating unit is 1/20 to 20/1.

In addition, in Formula (P-7), 1 represents the number of repetitions of the oxyalkylene unit and represents an integer of 1 to 30.

In Formula (P-20), X represents an amide group, a nitrile group, an amino hydrochloride, or a formamide group.

Other specific examples of the nitrogen-containing polymer include a polymer (poly(2-hydroxypropyldimethylammonium chloride)) formed by condensation polymerization of dimethylamine and epichlorohydrin. The polymer formed by condensation polymerization of dimethylamine and epichlorohydrin is a polymer containing the repeating unit represented by Formula (3).

In addition, examples of the known nitrogen-containing polymer include the nitrogen-containing polymers described in paragraphs “0036” to “0071” of JP1999-255841A (JP-H11-255841A), paragraphs “0025” to “0039” of JP2001-106714A, paragraphs “0062” to “0065” of JP2004-115675A, paragraphs “0051” to “0055” of JP2005-002196A, paragraphs “0097” to “0111” of JP2005-097636A, paragraphs “0026” and “0027” of JP2015-166463A, paragraphs “0037” to “0048” of JP2017-075243A, and paragraphs “0062” to “0069” of JP2021-021020A.

As the nitrogen-containing polymer, commercially available products can also be used.

Examples of the commercially available product of the nitrogen-containing polymer include PAA-HCL-01 (“PAA” is a registered trademark, and the same applies hereinafter), PAA-HCL-03, PAA-HCL-05, PAA-SA, PAA-01, PAA-03, PAA-05, PAA-08, PAA-15C, PAA-25, PAA-D19A, PAA-D11, PAA-1123, PAA-U5000, PAA-U7030, PAA-N5000, PAS-21CL, PAS-21, PAS-M-1L, PAS-M-1, PAS-M-1A, PAS-H-1L, PAS-H-5L, PAS-H10L, PAS-24, PAS-92, PAS-92A, PAS-2401, PAS-A-1, PAS-A-5, PAS-2141CL, PAS-2223, PAS-880, PAA-1151, PAS-410L, PAS-410SA, PAS-2251, PAS-84, and PAS-2351. The aforementioned products are manufactured by Nittobo Medical Co., Ltd..

Examples of the commercially available product of the nitrogen-containing polymer other than those described above include Catiomaster (registered trademark) PD-7 of PD series, Catiomaster (registered trademark) PE-30, EPA-SK01, and PAE-01. The aforementioned products are manufactured by Yokkaichi Chemical Co., Ltd.

The weight average molecular weight of the nitrogen-containing polymer is preferably 1,000 or more, more preferably 2,000 or more, and still more preferably 4,000 or more. The upper limit of the weight average molecular weight of the nitrogen-containing polymer is not particularly limited, but is, for example, 400,000 or less, preferably 200,000 or less, and more preferably 100,000 or less.

From the viewpoint that the Si selective removability is more excellent, in a case where the nitrogen-containing polymer has a primary amine structure, a secondary amine structure, a tertiary amine structure, or a quaternary ammonium salt structure, the total content of the structures is preferably 0.0005 to 0.020 mol/g, more preferably 0.001 to 0.015 mol/g, and still more preferably 0.003 to 0.012 mol/g with respect to the total mass of the nitrogen-containing polymer.

The content of the nitrogen-containing polymer is preferably 0.01 to 10.0 mass %, more preferably 0.05 to 5.0 mass %, still more preferably 0.1 to 2.0 mass %, and particularly preferably 0.1 to 1.0 mass % with respect to the total mass of the treatment liquid.

The nitrogen-containing polymer may be used alone or in combination of two or more kinds thereof. In a case where two or more kinds of nitrogen-containing polymers are used in combination, the total amount thereof is also preferably the above-described preferred content.

### [Quaternary Ammonium Hydroxide]

The treatment liquid according to an embodiment of the present invention contains a quaternary ammonium hydroxide.

The quaternary ammonium hydroxide is a compound different from the nitrogen-containing polymer.

The quaternary ammonium hydroxide is a compound composed of a quaternary ammonium cation and a hydroxide anion (OH⁻). The quaternary ammonium hydroxide is not particularly limited, but is preferably a compound represented by Formula (a).

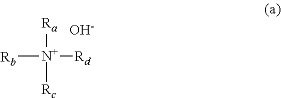

In Formula (a), Rₐ to R_{d} each independently represent an alkyl group which may have a substituent.

The alkyl group may be linear or branched, and is preferably linear. The number of carbon atoms in the alkyl group is preferably 1 to 10, more preferably 1 to 6, and still more preferably 1 to 4.

Examples of the substituent include a hydroxy group. In addition, a methylene group constituting the alkyl group may be substituted with a divalent substituent such as —O—.

In addition, the alkyl group which may have two substituents selected from Rₐ to R_{d} may be bonded to each other to form a ring. The ring to be formed may be an alicyclic ring or an aromatic ring, and is preferably an alicyclic ring.

Specific examples of the compound represented by Formula (a) include tetramethylammonium hydroxide, ethyltrimethylammonium hydroxide, tetraethylammonium hydroxide, tetrapropylammonium hydroxide, tetrabutylammonium hydroxide, methyltris(2-hydroxyethyl)ammonium hydroxide, trimethyl(2-hydroxyethyl)ammonium hydroxide, triethyl(2-hydroxyethyl)ammonium hydroxide, dimethylbis(2-hydroxyethyl)ammonium hydroxide, methyltris(2-hydroxyethyl)ammonium hydroxide, and tetra(2-hydroxyethyl)ammonium hydroxide.

Among these, tetramethylammonium hydroxide, ethyltrimethylammonium hydroxide, tetrabutylammonium hydroxide, or methyltris(2-hydroxyethyl)ammonium hydroxide is preferable.

The content of the quaternary ammonium hydroxide is preferably 0.1 to 15.0 mass %, more preferably 1.0 to 10.0 mass %, and still more preferably 2.0 to 6.0 mass % with respect to the total mass of the treatment liquid.

The quaternary ammonium hydroxide may be used alone or in combination of two or more kinds thereof. In a case where two or more kinds of quaternary ammonium hydroxides are used in combination, the total amount thereof is also preferably the above-described preferred content.

The molecular weight of the quaternary ammonium hydroxide is preferably 90 to 1,000, more preferably 90 to 500, and still more preferably 90 to 300.

The mass ratio of the content of the quaternary ammonium hydroxide to the content of the nitrogen-containing polymer is preferably 0.1 to 200.0, more preferably 0.5 to 100.0, and still more preferably 1.0 to 50.0.

### [Organic Solvent]

The treatment liquid according to an embodiment of the present invention contains an organic solvent having an SP value of 25 MPa^{1/2} or more.

The SP value of the organic solvent refers to a value calculated using the above Formula (S) by the above method. From the viewpoint that the Si selective removability is more excellent, the SP value of the organic solvent is preferably 26.0 MPa^{1/2} or more, more preferably 28.0 MPa^{1/2} or more, and still more preferably 30.0 MPa^{1/2} or more. The upper limit is not particularly limited, but is 48.0 MPa^{1/2} or less, and preferably 35.0 MPa^{1/2} or less.

The organic solvent is usually in a liquid state under the condition of 25° C.

The organic solvent is not particularly limited as long as the SP value is 25 MPa^{1/2} or more. Examples of the organic solvent include an alcohol-based solvent, an amide-based solvent, and a sulfur-containing solvent.

Examples of the alcohol-based solvent include a polyol, an alkoxyalcohol, a saturated aliphatic monohydric alcohol, an unsaturated non-aromatic monohydric alcohol, an alcohol having a ring structure, and an alcohol having an amino group (—NH₂, —NHR, or —NRR′, where R and R′ represents a substituent).

Examples of the polyol include ethylene glycol, diethylene glycol, propylene glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, and glycerol (glycerin).

Examples of the saturated aliphatic monohydric alcohol include methanol and ethanol.

Examples of the unsaturated non-aromatic monohydric alcohol include propargyl alcohol.

Examples of the alcohol having a ring structure include 1,3-cyclopentanediol.

Examples of the alcohol having an amino group include methanolamine, monoethanolamine, diethanolamine, and 1-amino-2-propanol.

Examples of the glycol-based solvent include ethylene glycol, propylene glycol, diethylene glycol, dipropylene glycol, and triethylene glycol.

Examples of the amide-based solvent include formamide, N-methylformamide, acetamide, and N-methylacetamide.

Examples of the sulfur-containing solvent include dimethyl sulfone, dimethyl sulfoxide, and sulfolane.

It is preferable that the organic solvent is a compound not containing an amide structure (—NHCO—). In addition, from the viewpoint that the Si selective removability is more excellent, the organic solvent is also preferably a compound having at least one of a hydroxy group or an amino group. The organic solvent may also be a compound having both a hydroxy group and an amino group.

From the viewpoint that the Si selective removability is more excellent, among the organic solvents listed above, ethylene glycol, monoethanolamine, diethanolamine, dimethyl sulfoxide, or sulfolane is preferable, and monoethanolamine or diethanolamine is more preferable.

The content of the organic solvent is not particularly limited, but is preferably 15 to 90 mass %, more preferably 30 to 80 mass %, and still more preferably 45 to 70 mass % with respect to the total mass of the treatment liquid from the viewpoint that the Si selective removability is excellent.

The organic solvent may be used alone or in combination of two or more kinds thereof. That is, from the viewpoint that the Si selective removability is more excellent, it is also preferable to mix two or more kinds of organic solvents having an SP value of 25 MPa^{1/2} or more.

In a case where two or more kinds of organic solvents are used in combination, the total content thereof is preferably the above-described preferred content.

The ratio of the content of the nitrogen-containing polymer to the content of the organic solvent is not particularly limited, but is preferably 0.001 to 1.00, more preferably 0.005 to 0.10, still more preferably 0.01 to 0.05, and particularly preferably 0.01 to 0.02.

### [Water]

The treatment liquid according to an embodiment of the present invention contains water.

As the water, water subjected to purification treatment, such as distilled water, ion exchanged water, and ultrapure water is preferable, and ultrapure water used for manufacturing a semiconductor is more preferable. Water contained in the treatment liquid may contain a trace amount of components that are unavoidably mixed in.

The content of water is not particularly limited. However, from the viewpoint that the Si selective removability is more excellent, the content of water is preferably 5 to 95 mass %, more preferably 20 to 80 mass %, and still more preferably 30 to 50 mass % with respect to the total mass of the treatment liquid.

In addition, the ratio of the content of water to the content of the organic solvent is not particularly limited, but is preferably 0.1 to 10, more preferably 0.2 to 3.0, and still more preferably 0.5 to 1.0.

### [Optional Components]

The treatment liquid may contain optional components other than the components described above.

Hereinafter, the optional components that can be contained in the treatment liquid are described in detail.

### (Other Organic Solvents)

The treatment liquid may contain organic solvents having an SP value of less than 25 MPa^{1/2} (other organic solvents).

From the viewpoint that the Si selective removability is more excellent, in a case where two or more kinds of solvents selected from the group consisting of the above-described organic solvent (having an SP value of 25 MPa^{1/2} or more) and the other organic solvents (having an SP value of less than 25 MPa^{1/2}) are mixed, the SP value of the mixed solvent is preferably 26.0 MPa^{1/2} or more, more preferably 28.0 MPa^{1/2} or more, and still more preferably 30.0 MPa^{1/2} or more. The upper limit is not particularly limited, but is, for example, 48.0 MPa^{1/2} or less, and preferably 35.0 MPa^{1/2} or less.

The SP value of the mixed solvent is a value obtained by adding the values obtained by multiplying the SP values of the respective solvents to be mixed by the contents (on a volume basis) of the respective solvents in the mixed solvent.

### (Basic Compound)

The treatment liquid may contain a basic compound.

The basic compound is a compound that exhibits alkalinity (more than pH of 7.0) in an aqueous solution.

Examples of the basic compound include an organic base, an inorganic base, and salts thereof.

It is noted that the basic compound does not contains the quaternary ammonium hydroxide, the organic solvent, and the nitrogen-containing polymer.

Examples of the organic base include a quaternary ammonium salt, an alkylamine compound or a salt thereof, an amine oxide compound, a nitro compound, a nitroso compound, an oxime compound, a ketoxime compound, an aldoxime compound, a lactam compound, and an isocyanide compound.

As the alkylamine compound, a trialkylamine compound is preferable. The alkyl group moiety of the alkylamine compound may have a substituent. The substituent is not particularly limited, but examples thereof include a hydroxy group and a phenyl group. A methylene group constituting the alkyl group moiety may be substituted with a divalent linking group such as —O—. In addition, the alkyl group moieties may be bonded to each other to form a ring.

In addition, the trialkylamine compound may form a salt with the acid exemplified as the acid forming a salt with the divalent linking group represented by Formula (X1).

Specific examples of the trialkylamine compound include methylamine, ethylamine, dimethylamine, diethylamine, trimethylamine, triethylamine, N-methyldiethanolamine, N-ethyldiethanolamine, N,N-dimethylethanolamine, N-methylmorpholine, N-ethylmorpholine, and salts thereof.

It is noted that the quaternary ammonium salt as an optional component is a compound different from the quaternary ammonium hydroxide.

Examples of the inorganic base include alkali metal hydroxides such as sodium hydroxide and potassium hydroxide, alkaline earth metal hydroxides, and ammonia or salts thereof.

The content of the basic compound is not particularly limited, but is preferably 0.1 mass % or more and more preferably 0.5 mass % or more with respect to the total mass of the treatment liquid. The upper limit thereof is not particularly limited, but is preferably 20.0 mass % or less with respect to the total mass of the treatment liquid.

It is also preferable that the basic compound is adjusted such that the pH range of the treatment liquid, which is described later, is in a preferred range within the above preferred range.

### (Acidic Compound)

The treatment liquid may contain an acidic compound.

The acidic compound is an acidic compound that exhibits acidity (less than pH of 7.0) in an aqueous solution.

Examples of the acidic compound include an inorganic acid, an organic acid, and salts thereof.

Examples of the inorganic acid include sulfuric acid, hydrochloric acid, phosphoric acid, nitric acid, hydrofluoric acid, perchloric acid, hypochlorous acid, and salts thereof.

Examples of the organic acid include a carboxylic acid, a sulfonic acid, and salts thereof.

Examples of the carboxylic acid include formic acid, acetic acid, propionic acid, and a lower (1 to 4 carbon atoms) aliphatic monocarboxylic acid such as butyric acid, and salts thereof.

Examples of the sulfonic acid include methanesulfonic acid, benzenesulfonic acid, p-toluenesulfonic acid (tosylic acid), and salts thereof.

The content of the acidic compound is not particularly limited, but is preferably 0.1 mass % or more and more preferably 0.5 mass % or more with respect to the total mass of the treatment liquid. The upper limit thereof is not particularly limited, but is preferably 20.0 mass % or less with respect to the total mass of the treatment liquid.

It is also preferable that the acidic compound is adjusted such that the pH range of the treatment liquid, which is described later, is in a preferred range within the above preferred range.

### (Surfactant)

The treatment liquid may contain a surfactant.

The surfactant is not particularly limited as long as it is a compound having a hydrophilic group and a hydrophobic group (lipophilic group) in one molecule. Examples of the surfactant include an anionic surfactant, a cationic surfactant, and a nonionic surfactant.

Examples of the hydrophobic group contained in the surfactant include an aliphatic hydrocarbon group, an aromatic hydrocarbon group, and a combination thereof.

In a case where the hydrophobic group includes an aromatic hydrocarbon group, the number of carbon atoms of the hydrophobic group is preferably 6 or more and more preferably 10 or more.

In a case where the hydrophobic group is composed of only an aliphatic hydrocarbon group without containing an aromatic hydrocarbon group, the number of carbon atoms in the hydrophobic group is preferably 8 or more and more preferably 10 or more. The upper limit of the number of carbon atoms of the hydrophobic group is not particularly limited, but is preferably 24 or less and more preferably 20 or less.

As the surfactant, a nonionic surfactant having a hydrophilic-lipophilic balance (HLB) value of 12.0 to 15.0, described in paragraphs “0029” and subsequent paragraphs of JP2021-009885A is also preferable. The HLB value in this case is preferably 12.5 to 14.0 and more preferably 12.5 to 13.5.

The HLB value is a value representing the degree of affinity of a surfactant for water and a water-insoluble organic compound. The HLB value is typically defined by following Formula (G).

Formula (G): HLB value=20×formula weight of hydrophilic portion of surfactant/molecular weight of surfactant

Formula (G) can be defined in a nonionic surfactant.

Specific examples of the surfactant include polyoxyalkylene alkyl ether, polyoxyalkylene alkylphenyl ether, polyoxyethylene fatty acid ester, polyoxyethylene sorbitan fatty acid ester, polyoxyethylene sorbitol fatty acid ester, glycerin fatty acid ester, and oleic acid triethanolamine.

The content of the surfactant is not particularly limited, but is preferably 10 ppm by mass or more and more preferably 30 ppm by mass or more with respect to the total mass of the treatment liquid. The upper limit is not particularly limited, but is preferably 10 mass % or less and more preferably 5 mass % or less with respect to the total mass of the treatment liquid from the viewpoint of suppressing foaming of the treatment liquid.

### (Corrosion Inhibitor)

The treatment liquid may contain a corrosion inhibitor.

The corrosion inhibitor is added to the treatment liquid for the purpose of preventing etching of other materials present on the object to be treated described later.

It is noted that the corrosion inhibitor does not include the organic solvent and the nitrogen-containing polymer.

The type of the corrosion inhibitor is appropriately selected depending on the properties of other materials present in the object to be treated.

Examples of the corrosion inhibitor include an amine compound, an imine compound, a thiol compound, and a thioether compound. Among these, an imine compound is preferable, and an unsaturated heterocyclic compound containing nitrogen is more preferable.

Examples of the unsaturated heterocyclic compound containing nitrogen include pyridine, triazine, imidazole, benzimidazole, purine, and xanthine, and derivatives thereof.

The content of the corrosion inhibitor is not particularly limited, but is preferably 0.1 mass % or more and more preferably 1 mass % or more with respect to the total mass of the treatment liquid. The upper limit is not particularly limited, but is preferably 10 mass % or less, and more preferably 5 mass % or less with respect to the total mass of the treatment liquid.

### <Properties of Treatment Liquid for Manufacturing Semiconductor>

Hereinafter, the chemical properties and physical properties exhibited by the treatment liquid will be described.

[pH]

From the viewpoint that the Si selective removability is more excellent, the pH of the treatment liquid is not particularly limited, but is preferably 7.0 or more, more preferably 11.0 or more, and still more preferably 13.0 or more. The upper limit of the pH of the treatment liquid is not particularly limited, but is preferably 15.0 or less.

In the present specification, the pH of the treatment liquid is a value obtained by measuring the pH of the treatment liquid at 25° C. using a pH meter (F-51 (trade name) manufactured by Horiba, Ltd.).

### [Coarse Particles]

It is preferable that the treatment liquid does not substantially contain coarse particles.

The “coarse particle” means particles having a diameter of 0.2 um or more in a case where the shape of the particle is regarded as a sphere. Further, the expression “substantially not containing coarse particles” indicates that in a case where the treatment liquid is measured using a commercially available measuring device in a light scattering type in-liquid particle measurement system, the number of particles having a particle diameter of 0.2 μm or more in 1 mL of the treatment liquid is 10 or less. The lower limit is preferably 0 or more.

The coarse particles contained in the treatment liquid are particles such as dust, dirt, organic solid substances, and inorganic solid substances contained as impurities in the raw material, particles such as dust, dirt, organic solid substances, and inorganic solid substances brought in as contaminants during the preparation of the treatment liquid, and the like, and the coarse particles that are finally present as particles without being dissolved in the treatment liquid.

Examples of a method of measuring the content of the coarse particles include a method of performing measurement in a liquid phase using a commercially available measuring device in a light scattering type in-liquid particle measurement system using a laser as a light source.

Examples of a method of removing the coarse particles include a filtering treatment.

### <Method of Producing Treatment Liquid for Manufacturing Semiconductor>

As a method of producing a treatment liquid, for example, a known production method can be used.

The method of producing a treatment liquid may include one or more steps selected from the step group consisting of a treatment liquid preparation step, a filtration step, and a static elimination step.

Hereinafter, the steps which may be included in the preparation process of the treatment liquid will be described in detail. In addition, the container storing the treatment liquid is also described in detail.

Each step in the method of preparing a treatment liquid is preferably performed in a clean room.

It is preferable that the clean room satisfies the 14644-1 clean room standard. Further, it is preferable that the clean room preferably satisfies any one of International Organization for Standardization (ISO) Class 1, ISO Class 2, ISO Class 3, or ISO Class 4, more preferable that the clean room satisfies ISO Class 1 or ISO Class 2, and still more preferable that the clean room satisfies ISO Class 1.

### [Treatment Liquid Preparation Step]

Examples of the treatment liquid preparation step include preparing respective components of a nitrogen-containing polymer, a quaternary ammonium hydroxide, an organic solvent, water, and optional components, and then mixing the respective components to prepare a treatment liquid. In the treatment liquid preparation step, the order of mixing the respective components is not particularly limited.

In addition, the treatment liquid may be prepared by preparing a concentrated solution having a lower content of one or more solvents selected from the group consisting of an organic solvent, water, and the like than a content of solvent at the time of use, and diluting the concentrated solution with a diluent (an organic solvent or water, or both) at the time of use to adjust the content of each component to a predetermined content. After diluting the concentrated solution with the diluent, the treatment liquid may be prepared by adjusting the pH thereof to a set value using a basic compound or an acidic compound. In a case where the concentrated solution is diluted, a predetermined amount of the diluent may be added to the concentrated solution, or a predetermined amount of the concentrated solution may be added to the diluent.

### [Filtration Step]

The method of preparing a treatment liquid may include a filtration step of filtering the treatment liquid in order to remove foreign matters, coarse particles, and the like from the treatment liquid.

Examples of the filtering method include known filtering methods, and filtering using a filter is preferable.

Examples of the filter used for filtering include filters used for known filtering.

Examples of the material constituting the filter include a fluororesin such as polytetrafluoroethylene (PTFE), polyamide resins such as nylon, and polyolefin resins (including high-density and ultra-high-molecular-weight polyolefin resins) such as polyethylene and polypropylene (PP). Polyamide resin, PTFE, or polypropylene (including high-density polypropylene) is preferable.

By using a filter made of the above materials, it is possible that foreign matters having high polarity, which are likely to cause defects, are more effectively removed from the treatment liquid.

The critical surface tension of the filter is preferably 70 mN/m or more. The upper limit of the critical surface tension is preferably 95 mN/m or less. In particular, the critical surface tension is more preferably 75 to 85 mN/m.

The value of the critical surface tension is a nominal value of the manufacturers.

High-polarity foreign matters which are likely to cause defects can be more effectively removed from the treatment liquid by using a filter having a critical surface tension in the above range.

The pore size of the filter is preferably 0.001 to 1.0 μm, more preferably 0.02 to 0.5 μm, and still more preferably 0.01 to 0.1 μm. In a case where the pore size of the filter is within the above range, it is possible to remove fine foreign matters from the treatment liquid while filter clogging is suppressed.

The filter may be a combination two or more kinds of filters.

The filtering using a first filter may be performed once or two or more times.

In a case where filtering is performed two or more times by combining a first filter and a second filter different from the first filter, the filters may be the same or different from each other, and it is preferable that the filters are different from each other. It is preferable that the first filter and the second filter are different from each other in at least one of the pore size or the constituent material.

It is preferable that the pore size of the second and subsequent filtering is the same as or smaller than the pore size of the first filtering. Further, first filters having different pore sizes may be combined within the above range of the pore size of the filter. For the pore size, a nominal value of the filter manufacturers can be referred to.

Examples of the filter include filters manufactured by Nihon Pall Ltd., Advantec Toyo Kaisha, Ltd., Nihon Entegris G. K., and KITZ Micro Filter Corporation.

Specific examples thereof include a P-nylon filter made of polyamide (pore size: 0.02 μm, critical surface tension: 77 mN/m, manufactured by Nihon Pall Ltd.), a PE clean filter made of high-density polyethylene (pore size: 0.02 μm, manufactured by Nihon Pall Ltd.), and a PE clean filter made of high-density polyethylene (pore size: 0.01 μm, manufactured by Nihon Pall Ltd.).

As the second filter, for example, a filter formed of the same material as the first filter is exemplified.

The pore size of the second filter may be the same as the pore size of the first filter.

In a case where the pore size of the second filter is smaller than the pore size of the first filter, the ratio of the pore size of the second filter to the pore size of the first filter (pore size of second filter/pore size of first filter) is preferably 0.01 to 0.99, more preferably 0.1 to 0.9, and still more preferably 0.3 to 0.9. In a case where the pore size of the second filter is within the range, fine foreign matters mixed into the treatment liquid can be further removed.

For example, the filtering using the first filter may be performed, in a mixed liquid containing a part of the components of the treatment liquid, and the filtering using the second filter may be performed after the remaining components are mixed with the filtrate to prepare a treatment liquid.

It is preferable to a wash the filter to be used before filtering the treatment liquid.

The washing treatment is preferably a washing treatment using a liquid, and more preferably a washing treatment using the treatment liquid and a liquid containing the components contained in the treatment liquid.

The temperature of the treatment liquid during filtering is preferably room temperature (25° C.) or lower, more preferably 23° C. or lower, and still more preferably 20° C. or lower. The lower limit is preferably 0° C. or higher, more preferably 5° C. or higher, and still more preferably 10° C. or higher.

In a case where the temperature is the above-described temperature, the amounts of particle foreign matters and impurities contained in the treatment liquid are reduced, and thus filtering can be more efficiently performed.

### [Static Elimination Step]

The method of producing a treatment liquid may further include a static elimination step of subjecting the treatment liquid to static elimination.

### [Container]

As the container for storing the treatment liquid, for example, a known container can be used.

As the container, a container used for semiconductor applications, which has high cleanliness in the container and causes less elution of impurities, is preferable.

Examples of the container include “Clean Bottle” series (manufactured by Aicello Corporation) and “Pure Bottle” (manufactured by Kodama Plastics Co., Ltd.). In addition, from the viewpoint of preventing impurities from being mixed (contamination) into the raw materials and the treatment liquid, it is also preferable to use a multilayer container that has an inner wall having a six layer structure consisting of six kinds of resins or a multilayer container that has an inner wall having a seven layer structure consisting of seven kinds of resins.

Examples of the multilayer container include the container described in JP2015-123351A, the contents of which are incorporated herein by reference.

Examples of the material of the inner wall of the container include a first resin which is at least one selected from the group consisting of polyethylene resin, polypropylene resin, polyethylene-polypropylene resin, a second resin different from the first resin, and metals such as stainless steel, Hastelloy, Inconel, and Monel. In addition, it is preferable that the inner wall of the container is formed of or coated with the above-described materials.

As the second resin, a fluororesin (perfluororesin) is preferable.

In a case where a fluororesin is used, the elution of the oligomer of ethylene or propylene can be suppressed.

Examples of the container include a FluoroPurePFA composite drum (manufactured by Entegris, Inc.), and the containers described in page 4 of JP1991-502677A (JP-H3-502677A), page 3 of WO2004/016526A, and pages 9 and 16 of WO99/046309A.

As the inner wall of the container, for example, quartz and an electropolished metal material (metal material which has been electropolished) are also preferable in addition to fluororesin.

The metal material used for the electropolished metal material contains at least one selected from the group consisting of chromium (Cr) and nickel (Ni). The total content of Cr and Ni is preferably more than 25 mass % with respect to the total mass of the metal material. Examples of the metal material include stainless steel and a Ni—Cr alloy.

The total content of Cr and Ni in the metal material is preferably 25 mass % or more, and more preferably 30 mass % or more with respect to the total mass of the metal material. The upper limit is preferably 90 mass % or less with respect to the total mass of the metal material. Examples of the stainless steel include known stainless steels.

In particular, stainless steel containing 8 mass % or more of Ni is preferable, and austenitic stainless steel containing 8 mass % or more of Ni is more preferable.

Examples of the austenitic stainless steel include steel use stainless (SUS) 304 (Ni content: 8 mass %, Cr content: 18 mass %), SUS304L (Ni content: 9 mass %, Cr content: 18 mass %), SUS316 (Ni content: 10 mass %, Cr content: 16 mass %), and SUS316L (Ni content: 12 mass %, Cr content: 16 mass %).

Examples of the Ni—Cr alloy include known Ni—Cr alloys.

In particular, a Ni—Cr alloy having a Ni content of 40 to 75 mass % and a Cr content of 1 to 30 mass % is preferable.

Examples of the Ni—Cr alloy include Hastelloy, Monel, and Inconel. Specific examples of the Ni—Cr alloy include Hastelloy C-276 (Ni content: 63 mass %, Cr content: 16 mass %), Hastelloy-C (Ni content: 60 mass %, Cr content: 17 mass %), and Hastelloy C-22 (Ni content: 61 mass %, Cr content: 22 mass %).

The Ni—Cr alloy may further contain boron, silicon, tungsten, molybdenum, copper, or cobalt as necessary, in addition to the above-described alloys.

Examples of the method of electropolishing the metal material include known methods.

Specific examples of the method include the methods described in paragraphs “0011” to “0014” of JP2015-227501A and paragraphs “0036” to “0042” of JP2008-264929A, the contents of which are incorporated herein by reference.

It is preferable that the metal material is buffed.

Examples of the buffing method include known methods.

From the viewpoint that the unevenness of the surface of the metal material is easily reduced, the size of the abrasive grains used for finishing the buffing is preferably #400 or less. It is preferable that the buffing is performed before the electropolishing.

The metal material may be subjected to a treatment including one or a combination of two or more of buffing, pickling, magnetic fluid polishing, and the like, and the buffing is performed in a plurality of stages by changing the number of the size or the like of abrasive grains.

It is preferable that the inside of the container is washed before the container is filled with the treatment liquid.

The liquid used for washing can be appropriately selected according to the use application, and is preferably the treatment liquid or a liquid containing at least one of the components added to the treatment liquid.

From the viewpoint of preventing a change in the components in the treatment liquid during storage, the inside of the container may be substituted with an inert gas (for example, nitrogen and argon) having a purity of 99.99995 vol % or more. In particular, a gas having a low moisture content is preferable. In addition, during transportation and storage of the container storing the treatment liquid, the temperature may be any of normal temperature or controlled temperature. Above all, from the viewpoint of preventing deterioration, it is preferable to control the temperature in the range of −20 to 20° C.

### <Use Application of Treatment Liquid for Manufacturing Semiconductor>

It is preferable that the treatment liquid is used for manufacturing a semiconductor. More specifically, it is preferable that the treatment liquid is used for manufacturing a semiconductor element.

The treatment liquid can also be used in the step of manufacturing a semiconductor element. For example, the treatment liquid can be used for a treatment of a material made of silicon present on a substrate, an insulating film, a resist film, an antireflection film, an etching residue, an ashing residue (hereinafter, also simply referred to as a “residue”), and the like. The treatment liquid may be used for a treatment of a substrate after chemical mechanical polishing.

In particular, the treatment liquid is preferably used for a treatment of an object to be treated containing Si and SiGe (hereinafter, also simply referred to as an “object to be treated”). As the element obtained by treating the object to be treated with the treatment liquid, a field effect transistor (FET) is preferable, and a gate-all-around FET (GAA-FET) is more preferable. That is, it is preferable that the treatment liquid is used in the production process of the GAA-FET.

Incidentally, the GAA-FET refers to an FET having a structure in which a side surface portion of the channel between the drain and the source is covered with the gate over the entire circumference. Examples of the channel in the GAA-FET include a form in which the channel is formed of a nanosized wire-like member. In the production of the GAA-FET, for example, a process of selectively removing Si from an object to be treated having a nano-structure is included, and the treatment liquid according to an embodiment of the present invention can be preferably used in the process.

### <Method of Treating Object to be Treated>

Hereinafter, a method of treating an object to be treated containing Si and SiGe (object to be treated) using the treatment liquid according to an embodiment of the present invention will be described.

### [Object to be Treated]

The object to be treated contains Si and SiGe.

The object to be treated is not particularly limited as long as it contains Si and SiGe, and Si and SiGe are usually disposed on a substrate.

Here, the expression “on a substrate” includes any form of the front and back, the side surface, and the inside of the groove of the substrate.

In addition, the expression “Si and SiGe are disposed on a substrate” includes a case where Si and SiGe are disposed directly on the surface of the substrate and a case where Si and SiGe are disposed on the substrate via another layer.

In addition, the expression “Si and SiGe are disposed on a substrate” means that the existence form of Si and SiGe is not limited as long as Si and SiGe are present on the substrate at the same time. For example, Si and SiGe may be in contact with each other, or may be in contact with each other via another layer or member. In addition, a form in which Si and SiGe are present on the same substrate but are not in contact with each other may be adopted.

The substrate is not particularly limited, and examples thereof include a metal substrate, a semiconductor substrate, a conductive substrate other than a metal, a metal oxide substrate, a glass substrate, and a resin substrate. Among these, a semiconductor substrate is preferable.

Examples of the semiconductor substrate include a semiconductor wafer, a glass substrate for a photomask, a glass substrate for a liquid crystal display, a glass substrate for a plasma display, a substrate for a field emission display (FED), a substrate for an optical disk, a substrate for a magnetic disk, and a substrate for a magneto-optical disk.

Examples of the material constituting the semiconductor substrate include silicon, Group III-V compounds such as GaAs, and a combination thereof.

Examples of use application of the object to be treated include a dynamic random access memory (DRAM), a ferroelectric random access memory (FRAM) (registered trademark), a magnetoresistive random access memory (MRAM), a phase change random access memory (PRAM), a logic circuit, and a processor.

The form of Si or SiGe on the substrate may be any of forms in which Si or SiGe is arranged in a film form, a wiring form, a plate form, a columnar form, and a particle form.

The object to be treated may include a desired layer or structure, or both of them, in addition to Si and SiGe.

For example, one or more members selected from the group consisting of a metal wiring, a gate electrode, a source electrode, a drain electrode, an insulating layer, a ferromagnetic layer, and a non-magnetic layer may be disposed on the substrate.

The substrate may include an exposed integrated circuit structure.

Examples of the integrated circuit structure include an interconnection mechanism of a metal wire, a dielectric material and the like. Examples of the metal and alloy used for the interconnection mechanism include aluminum, a copper aluminum alloy, copper, nickel, nickel silicide, cobalt, cobalt silicide, ruthenium, platinum, gold, titanium, tantalum, tungsten, titanium nitride, and tantalum nitride. The substrate may include one or more layers made of a material selected from the group consisting of silicon oxide, silicon nitride, silicon carbide, and carbon-doped silicon oxide.

### [Treatment Method]

The method of treating an object to be treated according to an embodiment of the present invention (hereinafter, also referred to as the “present treatment method”) includes a step A of bringing an object to be treated containing Si and SiGe into contact with the above-described treatment liquid. By performing the present treatment method, Si in the object to be treated is selectively etched.

The object to be treated used in the present treatment method is as described above.

Examples of the method of bringing the object to be treated into contact with the treatment liquid include a method of immersing the object to be treated in the treatment liquid charged in a tank, a method of spraying the treatment liquid onto the object to be treated, a method of causing the treatment liquid to flow onto the object to be treated, and a method of combining these methods. The method of immersing the object to be treated in the treatment liquid is preferable.

Futher, in order to further increase a treatment rate with the treatment liquid, a mechanical stirring method may be used.

Examples of the mechanical stirring method include a method of circulating the treatment liquid on the object to be treated, a method of causing the treatment liquid to flow on the object to be treated or spraying the treatment liquid onto the object to be treated, and a method of stirring the treatment liquid with ultrasonic waves or megasonic waves. A treatment time of the step A can be appropriately adjusted.

The treatment time (contact time between the treatment liquid and the object to be treated) is preferably 0.25 to 10 minutes and more preferably 0.5 to 2 minutes.

The temperature of the treatment liquid during the treatment is preferably 20 to 100° C. and more preferably 40 to 80° C.

### (Other Steps)

The present treatment method may include other steps in addition to the step A.

Examples of the other steps include a formation step (for example, layer forming, etching, chemical mechanical polishing, and modification) of forming one or more structures selected from the group consisting of a metal wiring, a gate structure, a source structure, a drain structure, an insulating layer, a ferromagnetic layer, a non-magnetic layer, and the like, a resist formation step, an exposure step and a removal step, a heat treatment step, a washing step, and an inspection step.

The present treatment method may be performed at any stage of a back end of the line (BEOL), a middle of the line (MOL), or a front end of the line (FEOL), and is preferably performed in the front end of the line or the middle of the line.

### EXAMPLES

Hereinafter, the present invention is described in more detail with reference to Examples.

Materials, used amounts, ratios thereof, treatment contents, treatment procedures, and the like shown in the following Examples can be suitably modified without departing from the scope of the present invention. Therefore, the scope of the present invention should not be interpreted in a limited way by Examples to be described below.

### Preparation of Treatment Liquid

Ultrapure water and each component were mixed so as to have the contents shown in Table 1 below to obtain a mixed liquid. Then, the mixed liquid was thoroughly stirred with a stirrer to obtain a treatment liquid used in each of Examples and Comparative Examples. The content of the treatment liquid in Table 1 is mass basis, and the remaining of the total amount of the components is water.

Hereinafter, the components listed in Table 1 below are specifically shown.

### [Nitrogen-Containing Polymer]

PAA-03: Allylamine polymer (the following compound having a primary amine structure, weight average molecular weight: 3,000), manufactured by Nittobo Medical Co., Ltd.

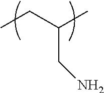

PAS-2251: Methyldiallylamine-maleic acid copolymer (the following compound having a tertiary amine structure), manufactured by Nittobo Medical Co., Ltd.

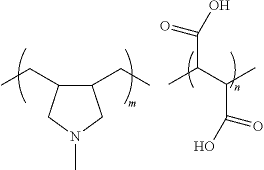

PAS-21: Diallylamine polymer (the following compound having a secondary amine structure, weight average molecular weight: 5,000), manufactured by Nittobo Medical Co., Ltd.

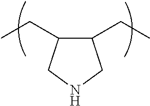

PAS-24: Diallyl methyl ethyl ammonium ethyl sulfate polymer (the following compound having a quaternary ammonium salt structure, weight average molecular weight: 37,000), manufactured by Nittobo Medical Co., Ltd.

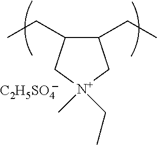

PD-7: Catiomaster (registered trademark) PD (co-condensate of dimethylamine and epichlorohydrin) (the following compound having a quaternary ammonium salt structure, weight average molecular weight: 5,000), manufactured by Yokkaichi Chemical Co., Ltd.

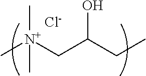

PAS-H-1L: Diallyldimethylammonium chloride polymer (the following compound having a quaternary ammonium salt structure, weight average molecular weight: 8,500), manufactured by Nittobo Medical Co., Ltd.

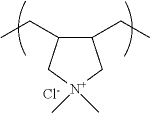

PEI: Lupasol (registered trademark) FG (branched polyethyleneimine, weight average molecular weight: 800), manufactured by BASF
PAS-92: Diallylamine hydrochloride-sulfur dioxide copolymer (the following compound having a secondary amine salt structure, weight average molecular weight: 5,000), manufactured by Nittobo Medical Co., Ltd.

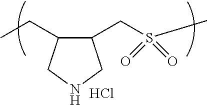

### [Organic Solvent]

DMSO: Dimethyl sulfoxide (SP value: 26.7 MPa^{1/2})
SL: Sulfolane (SP value: 26.4 MPa^{1/2})
EG: Ethylene glycol (SP value: 33.0 MPa^{1/2})
DEA: Diethanolamine (SP value: 26.6 MPa^{1/2})
MEA: Monoethanolamine (SP value: 31.1 MPa^{1/2})
EGME: Ethylene glycol monomethyl ether (SP value: 23.4 MPa^{1/2})

### [Quaternary Ammonium Hydroxide]

ETMAH: Ethyltrimethylammonium hydroxide
TMAH: Tetramethylammonium hydroxide
TBAH: Tetrabutylammonium hydroxide
THMAH: Tris(2-hydroxyethyl)methylammonium hydroxide

### [Water]

### Ultrapure Water

### <Evaluation>

The evaluations of the etching rate of SiGe (ER(SiGe)) by the treatment liquid, that is, the SiGe corrosion resistance, and the ratio of the etching rate of Si to SiGe (ERR (Si/SiGe)) by the treatment liquid, that is, the Si selective removability were performed according to the following procedure.

A SiGe layer (mass ratio: Si/Ge=4/1) was formed on a commercially available 12-inch silicon wafer by heteroepitaxy, and a chip obtained by cutting a square size of 2 cm by 2 cm from the wafer as a test piece. The thickness of the SiGe layer on the obtained test piece was measured with a spectroscopic ellipsometer (“Vace” manufactured by J.A. Woollam Japan). The test piece was put into a container filled with the treatment liquid of each of Examples or Comparative Examples, and the treatment liquid was stirred to perform the etching treatment for 20 minutes. The temperature of the treatment liquid was 40° C.

After the etching treatment, the test piece was washed with water, and dried by nitrogen blowing, and the thickness of the SiGe layer was measured with a spectroscopic ellipsometer. ER (SiGe) (Å/min) was calculated from the change in the thickness of the SiGe layer before and after the etching treatment. In addition, the same test as described above was performed on a test piece obtained by forming a Si layer on a SiGe wafer by heteroepitaxy, and ERR (Si/SiGe) was calculated.

ER (SiGe) and ERR (Si/SiGe) were evaluated based on the following evaluation standards.

It is preferable that ER (SiGe) has a smaller value, and an evaluation of C or higher for practical use. In addition, It is preferable that ERR (Si/SiGe) has a larger value, and an evaluation of C or higher for practical use.

### [Evaluation Criteria for ER (SiGe)]

A: less than 10 Å/min
B: 10 Å/min or more and less than 20 Å/min
C: 20 Å/min or more and less than 30 Å/min
D: 30 Å/min or more

### Evaluation Criteria for ERR (Si/SiGe)

A: 30 or more
B: 20 or more and less than 30
C: 10 or more and less than 20
D: less than 10

### <Results>

The blending of the treatment liquid and the evaluation results are shown in Table 1.

In the table, the “content” of each component represents a content (mass %) with respect to the total mass of the treatment liquid. The remaining of the total content of the components is water.

The “pH” in the table indicates a value obtained by measuring the pH of the treatment liquid with a pH meter (F-51 (trade name) manufactured by Horiba, Ltd.). The measurement temperature was 25° C.

TABLE 1

| | Nitrogen-containing | | | | Quaternary ammonium | | | | |
|---|---|---|---|---|---|---|---|---|---|
| | polymer | | Organic solvent | | hydroxide | | | | ERR |
| | | Content | | Content | | Content | | ER(SiGe) | (Si/SiGe) |
| | Type | (mass %) | Type | (mass %) | Type | (mass %) | pH | (Å/min) | (—) |
| Example 1 | PAA-03 | 1.0 | DMSO | 25.0 | ETMAH | 2.5 | 13.8 | C | C |
| Example 2 | PAA-03 | 1.0 | SL | 25.0 | ETMAH | 2.5 | 14.2 | C | C |
| Example 3 | PAA-03 | 1.0 | EG | 30.0 | ETMAH | 2.5 | 13.6 | B | C |
| Example 4 | PAA-03 | 1.0 | DEA | 30.0 | ETMAH | 2.5 | 13.5 | B | C |
| Example 5 | PAA-03 | 1.0 | DEA | 50.0 | ETMAH | 2.5 | 14.5 | B | B |
| Example 6 | PAA-03 | 1.0 | DEA | 50.0 | TMAH | 2.0 | 14.4 | B | B |
| Example 7 | PAA-03 | 1.0 | DEA | 50.0 | TBAH | 5.0 | 14.1 | B | B |
| Example 8 | PAA-03 | 1.0 | DEA | 50.0 | THMAH | 4.0 | 14.7 | B | B |
| Example 9 | PAA-03 | 1.0 | MEA | 60.0 | ETMAH | 2.5 | 14.5 | B | B |
| Example 10 | PAS-2251 | 1.0 | MEA | 60.0 | ETMAH | 2.5 | 14.6 | A | B |
| Example 11 | PAS-21 | 1.0 | MEA | 60.0 | ETMAH | 2.5 | 14.7 | B | A |
| Example 12 | PD-7 | 1.0 | MEA | 60.0 | ETMAH | 2.5 | 14.3 | A | B |
| Example 13 | PAS-24 | 1.0 | MEA | 60.0 | ETMAH | 2.5 | 14.6 | A | A |
| Example 14 | PAS-H-1L | 1.0 | MEA | 60.0 | ETMAH | 2.5 | 14.5 | A | A |
| Example 15 | PAS-H-1L | 1.0 | MEA | 30.0 | ETMAH | 2.5 | 13.7 | B | A |
| Example 16 | PAS-H-1L | 1.0 | DMSO | 30.0 | ETMAH | 2.5 | 13.8 | B | B |
| Example 17 | PAS-H-1L | 1.0 | MEA | 60.0 | TMAH | 2.0 | 14.2 | A | A |
| Example 18 | PAS-H-1L | 1.0 | MEA | 60.0 | TBAH | 5.0 | 14.3 | A | A |
| Example 19 | PAS-H-1L | 1.0 | MEA | 60.0 | THMAH | 4.0 | 14.6 | A | A |
| Example 20 | PAS-H-1L | 0.1 | MEA | 60.0 | ETMAH | 2.5 | 14.6 | A | A |
| Example 21 | PAS-H-1L | 0.01 | MEA | 60.0 | ETMAH | 2.5 | 14.6 | B | B |
| Example 22 | PAS-H-1L | 2.0 | MEA | 60.0 | ETMAH | 2.5 | 14.5 | A | A |
| Example 23 | PAS-H-1L | 5.0 | MEA | 60.0 | ETMAH | 2.5 | 14.4 | A | B |
| Comparative | — | — | DMSO | 50.0 | TMAH | 2.0 | 13.9 | D | D |
| Example 1 | | | | | | | | | |
| Comparative | PEI | 1.0 | SL | 50.0 | TMAH | 2.0 | 13.5 | D | D |
| Example 2 | | | | | | | | | |
| Comparative | PAS-92 | 1.0 | EGME | 50.0 | TMAH | 2.0 | 13.8 | D | D |
| Example 3 | | | | | | | | | |

From the results in Table 1, it was confirmed that the treatment liquid for manufacturing a semiconductor according to an embodiment of the present invention has excellent Si selective removability.

From the comparison between Examples 1 to 4 and Examples 5 to 10, it was confirmed that in a case where the content of the organic solvent was 40 mass % or more with respect to the total mass of the treatment liquid for producing a semiconductor, the Si selective removability was more excellent.

From the comparison between Examples 1 and 2 and Examples 3 and 4, and the comparison between Examples 15 and 16, it was confirmed that in a case where the organic solvent contains a compound having at least one of a hydroxy group or an amino group, the Si selective removability is more excellent.

From the comparison between Examples 12 to 19 and other Examples, it was confirmed that in a case where the nitrogen-containing polymer has a repeating unit having a quaternary ammonium salt structure, at least one of the Si selective removability or the SiGe corrosion resistance is more excellent.

From the comparison between Examples 10, 11, and 13 to 19 and other Examples, it was confirmed that in a case where the nitrogen-containing polymer has the repeating unit represented by Formula (1), at least one of the Si selective removability or the SiGe corrosion resistance is more excellent.

From the comparison between Examples 19, 20, and 22 and Examples 21 and 23, it was confirmed that in a case where the content of the nitrogen-containing polymer was 0.1 to 2.0 mass % with respect to the total mass of the treatment liquid, the Si selective removability was more excellent.

What is claimed is:

1. A treatment liquid for producing a semiconductor, the treatment liquid comprising:
a nitrogen-containing polymer;
a quaternary ammonium hydroxide;
an organic solvent having an SP value of 25 MPa^{1/2} or more; and
water,
provided that polyalkyleneimine is excluded from the nitrogen-containing polymer.

2. The treatment liquid for manufacturing a semiconductor according to claim 1,
wherein the treatment liquid is used for an object to be treated containing silicon germanium and silicon.

3. The treatment liquid for manufacturing a semiconductor according to claim 1,
wherein a content of the organic solvent is 40 mass % or more with respect to a total mass of the treatment liquid for producing a semiconductor.

4. The treatment liquid for manufacturing a semiconductor according to claim 1,
wherein the organic solvent does not include a compound having an amide structure.

5. The treatment liquid for manufacturing a semiconductor according to claim 1,
wherein the organic solvent is a compound having at least one of a hydroxy group or an amino group.

6. The treatment liquid for manufacturing a semiconductor according to claim 1,
wherein pH is more than 7.0.

7. The treatment liquid for manufacturing a semiconductor according to claim 1,
wherein pH is 11.0 or more.

8. The treatment liquid for manufacturing a semiconductor according to claim 1,
wherein a weight average molecular weight of the nitrogen-containing polymer is 1,000 or more.

9. The treatment liquid for manufacturing a semiconductor according to claim 1,
wherein the nitrogen-containing polymer contains a repeating unit having a structure selected from the group consisting of a primary amine structure, a secondary amine structure, a tertiary amine structure, and a quaternary ammonium salt structure.

10. The treatment liquid for manufacturing a semiconductor according to claim 9,
wherein the nitrogen-containing polymer contains a repeating unit having the quaternary ammonium salt structure.

11. The treatment liquid for manufacturing a semiconductor according to claim 1,
wherein the nitrogen-containing polymer contains a repeating unit selected from the group consisting of a repeating unit represented by Formula (1), a repeating unit represented by Formula (2), and a repeating unit represented by Formula (3), 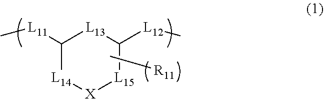
in Formula (1), L₁₁ to L₁₅ each independently represent a single bond or a divalent linking group,
X represents a divalent linking group containing a nitrogen atom,
R₁₁ represents a monovalent substituent, in a case where a plurality of R₁₁ are present, the plurality of R₁₁ each independently represent a monovalent substituent, and
n₁ represents an integer of 0 to 5, 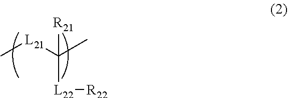
in Formula (2), L₂₁ represents a divalent linking group,
L₂₂ represents a single bond or a divalent linking group,
R₂₁ represents a hydrogen atom or a monovalent substituent, and
R₂₂ represents a monovalent substituent containing a nitrogen atom, 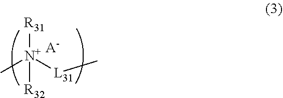
in Formula (3), L₃₁ represents a divalent linking group,
R₃₁ and R₃₂ each independently represent a monovalent substituent, and
A⁻ represents a monovalent anion.

12. The treatment liquid for manufacturing a semiconductor according to claim 11,
wherein the nitrogen-containing polymer contains the repeating unit represented by Formula (1).

13. The treatment liquid for manufacturing a semiconductor according to claim 1,
wherein a content of the nitrogen-containing polymer is 0.1 to 2.0 mass % with respect to the total mass of a treatment liquid for producing a semiconductor.

14. The treatment liquid for manufacturing a semiconductor according to claim 1,
wherein a content of the organic solvent is 40 mass % or more with respect to a total mass of the treatment liquid for producing a semiconductor, and
the organic solvent is a compound having at least one of a hydroxy group or an amino group.

15. The treatment liquid for manufacturing a semiconductor according to claim 1,
wherein a content of the organic solvent is 40 mass % or more with respect to a total mass of the treatment liquid for producing a semiconductor, and
pH is more than 7.0.

16. The treatment liquid for manufacturing a semiconductor according to claim 1,
wherein the organic solvent is a compound having at least one of a hydroxy group or an amino group, and
the nitrogen-containing polymer contains a repeating unit having a structure selected from the group consisting of a primary amine structure, a secondary amine structure, a tertiary amine structure, and a quaternary ammonium salt structure.

17. The treatment liquid for manufacturing a semiconductor according to claim 1,
wherein the organic solvent is a compound having at least one of a hydroxy group or an amino group, and
the nitrogen-containing polymer contains a repeating unit selected from the group consisting of a repeating unit represented by Formula (1), a repeating unit represented by Formula (2), and a repeating unit represented by Formula (3), 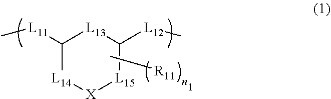
in Formula (1), L₁₁ to L₁₅ each independently represent a single bond or a divalent linking group,
X represents a divalent linking group containing a nitrogen atom,
R₁₁ represents a monovalent substituent, in a case where a plurality of R₁₁ are present, the plurality of R₁₁ each independently represent a monovalent substituent, and
n₁ represents an integer of 0 to 5, 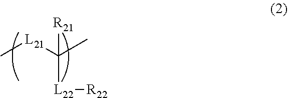
in Formula (2), L₂₁ represents a divalent linking group,
L₂₂ represents a single bond or a divalent linking group,
R₂₁ represents a hydrogen atom or a monovalent substituent, and
R₂₂ represents a monovalent substituent containing a nitrogen atom, 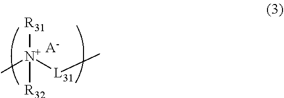
in Formula (3), L₃₁ represents a divalent linking group,
R₃₁ and R₃₂ each independently represent a monovalent substituent, and
A⁻ represents a monovalent anion.

18. The treatment liquid for manufacturing a semiconductor according to claim 1,
wherein the organic solvent is a compound having at least one of a hydroxy group or an amino group,
the nitrogen-containing polymer contains a repeating unit selected from the group consisting of a repeating unit represented by Formula (1), a repeating unit represented by Formula (2), and a repeating unit represented by Formula (3), and
a content of the nitrogen-containing polymer is 0.1 to 2.0 mass % with respect to the total mass of a treatment liquid for producing a semiconductor, 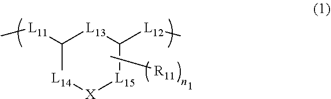
in Formula (1), L₁₁ to L₁₅ each independently represent a single bond or a divalent linking group,
X represents a divalent linking group containing a nitrogen atom,
R₁₁ represents a monovalent substituent, in a case where a plurality of R₁₁ are present, the plurality of R₁₁ each independently represent a monovalent substituent, and
n₁ represents an integer of 0 to 5, 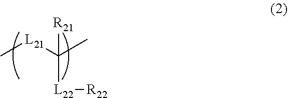
in Formula (2), L₂₁ represents a divalent linking group,
L₂₂ represents a single bond or a divalent linking group,
R₂₁ represents a hydrogen atom or a monovalent substituent, and
R₂₂ represents a monovalent substituent containing a nitrogen atom, 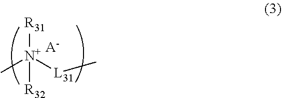
in Formula (3), L₃₁ represents a divalent linking group,
R₃₁ and R₃₂ each independently represent a monovalent substituent, and
A⁻ represents a monovalent anion.

19. The treatment liquid for manufacturing a semiconductor according to claim 1,
wherein a weight average molecular weight of the nitrogen-containing polymer is 1,000 or more, and
the nitrogen-containing polymer contains a repeating unit having a structure selected from the group consisting of a primary amine structure, a secondary amine structure, a tertiary amine structure, and a quaternary ammonium salt structure.

20. A method of treating an object to be treated, the method comprising:
bringing an object to be treated containing silicon germanium and silicon into contact with the treatment liquid for manufacturing a semiconductor according to claim 1 to remove the silicon.
